(19) United States
(12) Patent Application Publication
(10) Pub. No.: US 2026/0343748 A1
(43) Pub. Date: Oct. 29, 2026

(54) TRANS-INDUCTOR VOLTAGE REGULATOR INTEGRATED WITH COMPENSATION INDUCTOR AND POWER MODULE

(71) Applicant: JNV Semiconductor (Shanghai) Co., LTD., Shanghai (CN)

(72) Inventors: Xin ZHANG, Shanghai (CN); Yun LU, Shanghai (CN); Yu ZHANG, Shanghai (CN)

(73) Assignee: JNV Semiconductor (Shanghai) Co., LTD., Shanghai (CN)

(21) Appl. No.: 19/657,129

(22) Filed: Apr. 24, 2026

(30) Foreign Application Priority Data
Apr. 29, 2025 (CN) 2025105598503

(51) Int. Cl. H05K 1/14; H01F 27/24; H01F 27/28; H02M 3/00; H05K 1/02; H05K 1/181

(52) U.S. Cl. CPC H05K 1/145; H01F 27/24; H01F 27/28; H02M 3/003; H05K 1/0216; H05K 1/181; H05K 2201/042; H05K 2201/1003

(57) ABSTRACT

The present invention relates to the technical field of power electronics, and more particularly, to a trans-inductor voltage regulator integrated with compensation inductors, and a power module. Coupling inductor units and the compensation inductors are both integrated in a packaging housing, and each compensation inductor is connected in series between every two adjacent phases of secondary winding inductors; both ends of the compensation inductor may be arranged on different planes, respectively; and in the connection of every two adjacent phases of secondary winding inductors, a tail end of the previous phase of secondary winding inductor and one end of the corresponding compensation inductor are located on the same welding face, and a head end of the next phase of secondary winding inductor and the other end of the corresponding compensation inductor are located on the same welding face.

### CROSS-REFERENCE TO RELATED APPLICATION

The present application claims the priority of the following patent application: (1) the Chinese patent application filed on Apr. 29, 2025 before the CNIPA with the application number of 202510559850.3 and the title of "VOLTAGE STABILIZER INTEGRATED WITH COMPENSATION INDUCTOR AND POWER MODULE".

### TECHNICAL FIELD

The present invention relates to the technical field of electronic components, and more particularly, to a voltage stabilizer integrated with compensation inductors, and a power module.

### BACKGROUND

A trans-inductor voltage regulator (TLVR) is mainly applied in a multi-phase power scheme to supply power to high-current and high-power density systems such as a graphic processing unit (GPU) and a server. A transient response of a power supply can be optimized by coupling varying energy into an N-phase power supply through the trans-inductor voltage regulator when a system load makes fast, large dynamic steps.

As shown in FIG. 1, in the existing trans-inductor voltage regulator, main power circuit inductors (i.e., L1-LN) are used for coupling with secondary winding inductors (i.e., L12-LN2). It is necessary to add an additional compensation inductor Lc outside the trans-inductor voltage regulator to store and transfer energy during switch changeover. However, in practical applications, there are the following problems.
1. The additional compensation inductor will occupy a product space.
2. In some application scenarios, the compensation inductor will withstand an electrical stress several times an input voltage, which challenges the voltage resistance of the compensation inductor.
3. When both ends of each secondary winding inductor are not in the same printed circuit board (PCB) routing plane, an additional conductor will be required to connect every two adjacent secondary winding inductors head to tail, which in turn increases the complexity of routings.

For a clearer explanation of the aforementioned question 3, referring to FIG. 2, the trans-inductor voltage regulator includes main power circuit inductors (i.e., L1 and L2) and secondary winding inductors (i.e., L12 and L22). The main power circuit inductor L1 is coupled with the secondary winding inductor L12, and the main power circuit inductor L2 is coupled with the secondary winding inductor L22. A wire needs to be led out from the head end of the secondary winding inductor L12 and be connected to the compensation inductor, and at the same time, the tail end of the secondary winding inductor L12 needs to be connected to the head end of the secondary winding inductor L22. However, the tail end of the secondary winding inductor L12 and the head end of the secondary winding inductor L22 are not located on a welding face of the same circuit board, so it is necessary to add routings on upper and lower two circuit boards respectively, and then connect the routings on the two circuit boards by using an external connection wire to achieve the connection between the two circuit boards (i.e., a path L in FIG. 2), thereby increasing the complexity of the routings.

In view of this, overcoming the defects of the prior art is an urgent problem to be solved in this technical field.

### SUMMARY

The technical problem to be solved by the present invention is how to solve the problem that an additional conductor is required to connect secondary coupling windings head to tail since both ends of each secondary coupling winding are not in the same PCB routing plane in the prior art, thereby increasing the complexity of routings and leading to overlarge electrical stress borne by the compensation inductor.

The present invention adopts the following technical solutions.

In a first aspect, a trans-inductor voltage regulator integrated with compensation inductors is provided. The trans-inductor voltage regulator includes a packaging housing, a first circuit board, a second circuit board and integrated inductor units arranged between the first circuit board and the second circuit board, wherein the first circuit board and the second circuit board are arranged on both sides of the packaging housing, respectively;
each integrated inductor unit includes a plurality of coupling inductor units and at least one compensation inductor; at least one compensation inductor is arranged between every two adjacent coupling inductor units; each coupling inductor unit includes a primary circuit inductor and a secondary winding inductor, and the secondary winding inductor is coupled with the primary circuit inductor;
one end of the primary circuit inductor is used for connection with an input voltage, and the other end of the primary circuit inductor is used for connection with a power consumption end; and
one end of the compensation inductor is connected to the previous phase of secondary winding inductor, and the other end of the compensation inductor is connected to the next phase of secondary winding inductor.

In a second aspect, a power module is provided. The power module includes at least one trans-inductor voltage regulator integrated with compensation inductors according to the first aspect.

Compared with the prior art, the present invention has the following beneficial effects.

The coupling inductor units and the compensation inductors are all integrated in the packaging housing, and each compensation inductor is connected in series between every two adjacent phases of secondary winding inductors; both ends of the compensation inductor may be arranged on different planes, respectively; and in the connection of every two adjacent phases of secondary winding inductors, a tail end of the previous phase of secondary winding inductor and one end of the corresponding compensation inductor are located on the same welding face, and a head end of the next phase of secondary winding inductor and the other end of the corresponding compensation inductor are located on the same welding face. That is, it is ensured that both ends of the compensation inductor are located on the same welding face as both ends of the corresponding secondary winding inductor, the problem of line connection is solved, and no external routing is needed, such that the structure of the trans-inductor voltage regulator is more concise.

In another aspect, a high voltage borne by the original independent compensation inductor is evenly distributed on a plurality of compensation inductors, and the value of voltage borne by each compensation inductor is greatly reduced, thereby ensuring the stability of the trans-inductor voltage regulator.

### BRIEF DESCRIPTION OF FIGURES

.To describe the embodiments of the present invention or the technical solutions in the prior art more clearly, the following briefly introduces the accompanying drawings required for describing the embodiments or the descriptions in the prior art. Apparently, the accompanying drawings in the following description show merely some embodiments of the present invention, and a person of ordinary skill in the art may still derive other accompanying drawings from these accompanying drawings without creative efforts.

FIG. 1 is a schematic diagram of a circuit structure of the existing trans-inductor voltage regulator provided by an embodiment of the present invention;

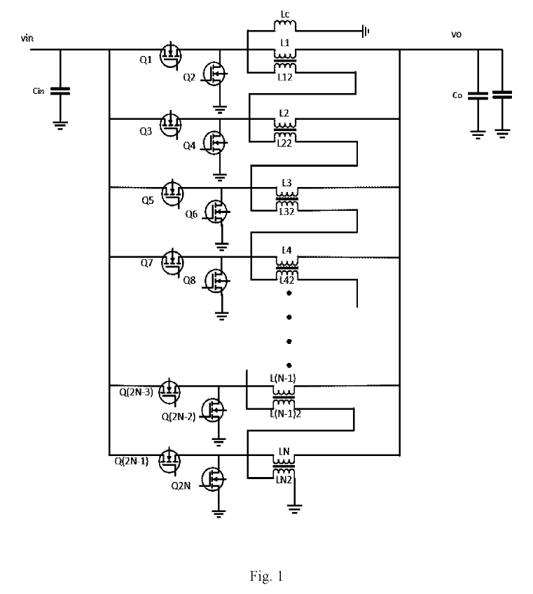

FIG. 2 is a schematic diagram of an internal structure of the existing trans-inductor voltage regulator provided by an embodiment of the present invention;

FIG. 3 is a schematic diagram of an external structure of a trans-inductor voltage regulator integrated with compensation inductors provided by an embodiment of the present invention;

FIG. 4 is a schematic diagram of an internal structure of a trans-inductor voltage regulator integrated with compensation inductors provided by an embodiment of the present invention;

FIG. 5 is a schematic diagram of a circuit structure of a trans-inductor voltage regulator integrated with compensation inductors provided by an embodiment of the present invention;

FIG. 6 is a schematic structural diagram of a first connection scheme provided by an embodiment of the present invention;

FIG. 7 is another schematic structural diagram of a first connection scheme provided by an embodiment of the present invention;

FIG. 8 is a schematic structural diagram of a plurality of phases of coupling inductor units provided by an embodiment of the present invention;

FIG. 9 is another schematic structural diagram of a plurality of phases of coupling inductor units provided by an embodiment of the present disclosure;

FIG. 10 is a schematic structural diagram of a second connection scheme provided by an embodiment of the present invention;

FIG. 11 is a schematic structural diagram of a third connection scheme provided by an embodiment of the present invention;

FIG. 12 is another schematic structural diagram of the third connection scheme provided by an embodiment of the present invention;

FIG. 13 is a schematic structural diagram of a fourth connection scheme provided by an embodiment of the present invention;

FIG. 14 is another schematic structural diagram of the fourth connection scheme provided by an embodiment of the present invention;

FIG. 15 is a schematic diagram of a switch unit provided by an embodiment of the present invention;

FIG. 16 is a schematic diagram of a circuit structure of a switch unit provided by an embodiment of the present invention; and

FIG. 17 is another schematic structural diagram of a trans-inductor voltage regulator provided by an embodiment of the present invention.

### DETAILED DESCRIPTION

In order to make the objectives, technical solutions and advantages of the present invention clearer, the following will describe the present invention in detail in conjunction with accompany drawings and embodiments. It should be understood that the specific embodiments described here are only used to explain the present invention, but not used to limit the present invention.

Unless the context otherwise required, throughout the entire specification and claims, the term "comprise/include" is construed to mean open inclusion, i.e., "including, but not limited to". In the description of the specification, the terms such as “an embodiment”, “some embodiments”, “an exemplary embodiment”, “an example”, “a specific example”, or “some examples” are intended to indicate that particular features, structures, materials or characteristics described in association with the embodiments or examples are included in at least one embodiment or example of the present disclosure. The schematic representation of the above terms does not necessarily refer to the same embodiment or example. Furthermore, the particular features, structures, materials or characteristics may be included in any one or more of the embodiments or examples in any appropriate manner. That is, although they may be carried in the embodiments or examples of the aforementioned terms due to factors such as the order and positions of their occurrence, it is not limited that they may be carried by one embodiment or example in a combined manner.

In the description of the present invention, the terms "first" and "second" are only for the purpose of description and should not be construed as indicating or implying relative importance or implicitly indicating the number of technical features indicated. Thus, the features defined by the terms "first" and "second" may include one or more of the features either explicitly or implicitly. In the description of the embodiments of the present disclosure, unless otherwise stated, the term "a plurality of" means two or more. In addition, for example, the same type of nouns will be described as two separate individuals in the description by adding "A" or "B" at the ends. In this case, the corresponding qualification of "A" and "B" features is only used for differentiating similar individual descriptions, and should not be interpreted as indicating or implying relative importance or implicitly specifying the number of the technical features indicated.

In the description of some embodiments, "coupling", "coupled" and "connected” and their derived expressions may be used. For example, the term "connected" may be used in some embodiments to indicate that two or more components are in direct physical or electrical contact with each other. For another example, the term "coupled" may be used in some embodiments to indicate that two or more components are in direct physical or electrical contact with each other. However, the term "connected" or "coupling" may also refer that two or more components are not in direct contact with each other, but still cooperate or interact with each other, e.g., “optical path coupling” or “wirelessly connected”. The embodiments disclosed herein are not necessarily limited to the content of the present invention.

Further, the technical features involved in various embodiments of the present invention described below may be combined with each other as long as they do not constitute a conflict with each other.

### Embodiment 1

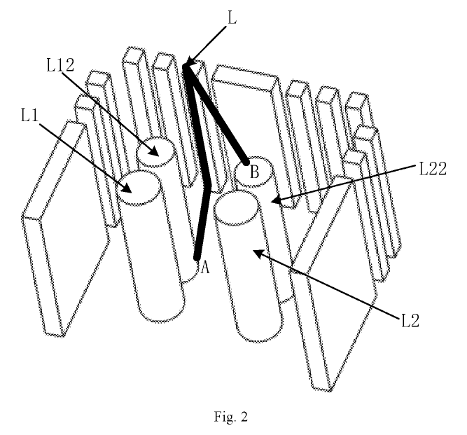

In the existing trans-inductor voltage regulator, taking two phases as an example, as shown in FIG. 2, when secondary winding inductors in each phase of coupling inductor unit are connected in series, both ends to be connected (i.e., an end A and an end B) are respectively located on different welding faces. It is necessary to add routings on upper and lower circuit boards respectively, and then connect the routings on the two circuit boards by using an external connection wire to achieve the connection between the two circuit boards (i.e. A path L in FIG. 2), thereby increasing the complexity of the routings. The need for additional routings greatly increases the complexity of the circuit design. In addition, more routings mean more welding spots, which undoubtedly increases the probability of errors in the production process as well as the difficulty of production cost and quality control.

To solve the above problems, the present embodiment proposes a trans-inductor voltage regulator integrated with compensation inductors. The trans-inductor voltage regulator includes an integrated inductor unit. The integrated inductor unit includes N phases of coupling inductor units and at least one compensation inductor. At least one compensation inductor is arranged between every two adjacent coupling inductor units. N is greater than or equal to 2. At least one compensation inductor is arranged between every two adjacent coupling inductor units (that is, the compensation inductor may be one compensation inductor or a plurality of compensation inductors which are connected in series or in parallel, and the present embodiment and the companying drawings take a case where only one compensation inductor is arranged between every two adjacent coupling inductor units as an example); or, the compensation inductor is only arranged between every two adjacent coupling inductor units among some coupling inductor units, while no compensation inductor is arranged between every two adjacent coupling inductor units among other coupling inductor units.

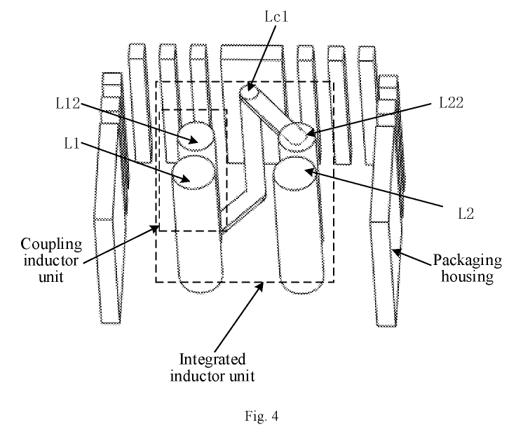

In one embodiment, as shown in FIG. 4, the integrated inductor unit may include two phases of coupling inductor units.

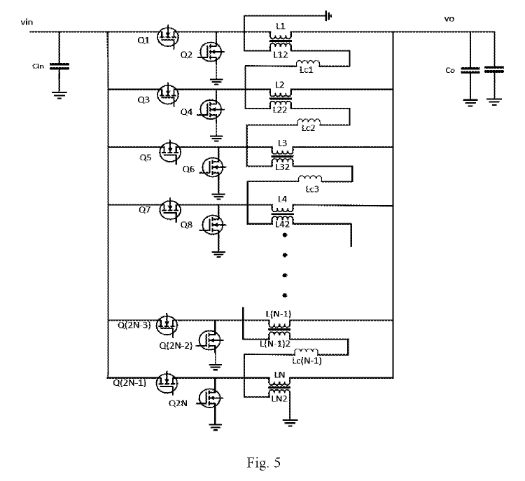

In one embodiment, as shown in FIG. 5, the integrated inductor unit may include N phases of coupling inductor units, wherein a compensation inductor is arranged between every two adjacent coupling inductor units (i.e., there are N - 1 compensation inductors in total).

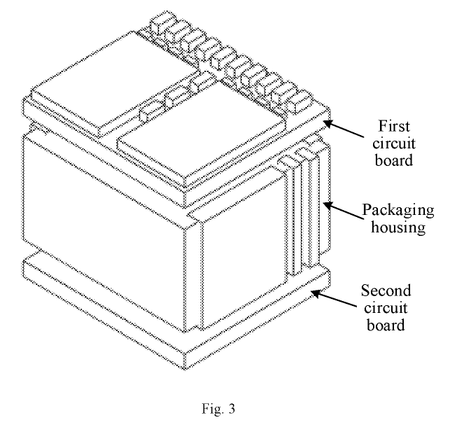

In order to facilitate the introduction of the trans-inductor voltage regulator, the structure of the trans-inductor voltage regulator is described by taking FIGS. 3 and 4 as an example. The trans-inductor voltage regulator includes a packaging housing, a first circuit board, a second circuit board and integrated inductor units arranged between the first circuit board and the second circuit board, wherein the first circuit board and the second circuit board are arranged on both sides of the packaging housing, respectively; each integrated inductor unit includes a plurality of coupling inductor units and at least one compensation inductor; at least one compensation inductor (i.e., Lc1 in FIG. 4) is arranged between every two adjacent coupling inductor units; each coupling inductor unit includes primary circuit inductors (including L1, L2, etc.) and secondary winding inductors (including L12, L22, etc.), and the secondary winding inductors are coupled with the primary circuit inductors; one end of each primary circuit inductor is used for connection with an input voltage, and the other end of the primary circuit inductor is used for connection with a power consumption end.

One end of the compensation inductor is connected to the previous phase of secondary winding inductor, and the other end of the compensation inductor is connected to the next phase of secondary winding inductor. Both ends of the compensation inductor are respectively located on the same welding face as both ends of the corresponding secondary winding inductor.

It should be noted here that the "previous phase" and the "next phase" are relative concepts. The previous phase of secondary winding inductor and the next phase of secondary winding inductor refer to the secondary winding inductors respectively corresponding to two adjacent coupling inductor units.

It should be noted here that one end of the secondary winding inductor at a head end is grounded, and the other end of the secondary winding inductor is connected to the compensation inductor or directly to the next phase of secondary winding inductor; and one end of the secondary winding inductor at a tail end is connected to the compensation inductor or directly to the previous phase of secondary winding inductor, and the other end of the secondary winding inductor at the tail end is grounded. Except for the secondary winding inductor at the head end and the secondary winding inductor at the tail end, the other secondary winding inductors have at least two connection relationships: the previous phase of secondary winding inductor is connected to the next phase of secondary winding inductor through the compensation inductor, or the previous phase of secondary winding inductor is connected to the next phase of secondary winding inductor through other conductive member.

As a physical protective barrier for the entire module, the packaging housing can resist physical shocks such as external collision and vibration at a mechanical level, and protect internal precision electronic components from damage. From an electrical point of view, the packaging housing provides good insulation performance, avoids electromagnetic interferences from an external environment, and ensures safe and stable operation of the inductor module in different electrical environments.

In one embodiment, the first circuit board is arranged at the top of the packaging housing, and the second circuit board is arranged at the bottom of the packaging housing. Both the first circuit board and the second circuit board are manufactured using a PCB technology. Each circuit board integrates interfaces thereon for connection with external circuits, such as pins and sockets, to achieve data interaction and power transmission between the module and other circuit systems. More specific details will not be described in the present embodiment.

Taking a case where the secondary winding inductor in the first phase of coupling inductor unit and the secondary winding inductor in the second phase of coupling inductor unit are connected in series as an example, the bottom of the secondary winding inductor in the first phase of coupling inductor unit needs to be connected to the top of the secondary winding inductor in the second phase of coupling inductor unit. In the prior art, additional wires are required to achieve the connection at both ends.

In one embodiment, the compensation inductor is integrated inside the packaging housing. Both ends of the two secondary winding inductors are connected in series through the compensation inductor, directly connected to the compensation inductor through the second circuit board, and then connected in series with the secondary winding inductors of the adjacent coupling inductor units through vertical interconnection (e.g., metal columns or embedded wires) of the first circuit board. The entire process does not require cross-layer external routing. The compensation inductor is embedded between every two adjacent coupling inductor units and connected through a short path, thereby reducing unnecessary external routings.

For the compensation inductor, at a circuit principle level, when a load current increases instantaneously, the duty cycle of pulse width modulation (PWM) of certain phase of a multi-phase power supply increases, causing the current flowing through the compensation inductor to increase. Since the secondary winding inductors of all phases are connected in series with the compensation inductors, the current change of the compensation inductors will couple to all the remaining phases of coupling inductor units, thereby increasing the current per phase. Similarly, when the load current decreases instantaneously, the current reduced by the compensation inductor will be coupled to all remaining phases of coupling inductor units, which is equivalent that all phases jointly respond to the change of transient current, and the total output current can quickly reach the current required by the load, thereby effectively improving the transient response of the multi-phase power supply.

In order to further describe the above embodiment, the present embodiment proposes a plurality of schemes to achieve the purpose that both ends of the compensation inductor are located on the same welding face as both ends of the corresponding secondary winding inductor.

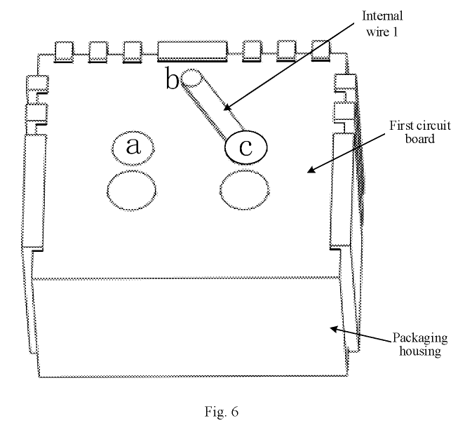

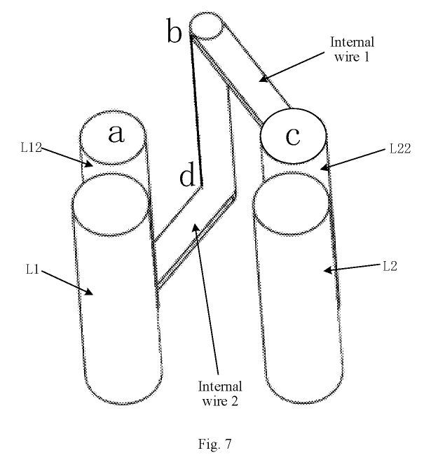

In one embodiment, as shown in FIGS. 6 and FIG. 7, the first scheme includes the following content: the first circuit board is provided with at least a first welding spot (a in figures), a second welding spot (b in figures) and a third welding spot (c in figures); the second circuit board is provided with at least a fourth welding spot (not shown in figures), a fifth welding spot (d in figures) and a sixth welding spot (not shown in figures); the second welding spot and the third welding spot are connected through an internal wire (i.e., an internal wire 1) in the first circuit board; the fourth welding spot and the fifth welding spot are connected through an internal wire (i.e., an internal wire 2) in the second circuit board; one end of the previous phase of secondary winding inductor is connected to the first welding spot, and the other end of the previous phase of secondary welding inductor is connected to the fourth welding spot; one end of the compensation inductor is connected to the fifth welding spot, and the other end of the compensation inductor is connected to the second welding spot; and one end of the next phase of secondary welding inductor is connected to the third welding spot, and the other end of the next phase of secondary welding inductor is connected to the sixth welding spot.

The fourth welding spot is located on the second circuit board opposite to the first welding spot, and the sixth welding spot is located on the second circuit board opposite to the third welding spot. There are at least three connection relationships for the first welding spot and other components: the first welding spot may be grounded, or the first welding spot is connected to the previous phase of compensation inductor, or the first welding spot is connected to the previous phase of secondary winding inductor. There are at least three connection relationships for the sixth welding spot and other components: the sixth welding spot may be grounded, or the sixth welding spot is connected to the previous phase of compensation inductor, or the sixth welding spot is connected to the previous phase of secondary winding inductor.

By reasonably designing the connection modes between the welding spots on the first circuit board and the second circuit board and the internal wires, both ends of the compensation inductor can be located on the same welding face as both ends of the corresponding secondary winding inductor, thereby simplifying the welding process and reducing the complexity of routings.

In the first circuit board, the second welding spot and the third welding spot are connected through the internal wire. In the second circuit board, the fourth welding spot and the fifth welding spot are connected through the internal wire.

In one embodiment, referring to FIG. 7, the coupling between the secondary winding inductors and the primary circuit inductors is based on a principle of electromagnetic induction. The current change of the primary circuit inductors may induce an electromotive force in the secondary winding inductors. One end of the secondary winding inductor may be connected to the first welding spot and grounded, which may provide a stable reference potential for the circuit and help stabilize the circuit operation. The other end of the secondary winding inductor is connected to the fourth welding spot, and establishes a connection with other circuits on the second circuit board through the fourth welding spot. One end of the compensation inductor is connected to the fifth welding spot, and the other end of the compensation inductor is connected to the second welding spot. Since the second welding spot and the third welding spot are connected through the internal wire in the first circuit board, and the fifth welding spot and the fourth welding spot are connected through the internal wire in the second circuit board, both ends of the compensation inductor are associated with both ends of the corresponding secondary winding inductor, and are located on the same welding face (connected through the welding spots) as both ends of the corresponding secondary winding inductor. One ends of the secondary winding inductors in the adjacent coupling inductor units are connected to the third welding spot, connected to the second welding spot through the internal wire in the first circuit board, and then connected to one end of the compensation inductor, completing a series connection relationship between the secondary winding inductors in the whole circuit.

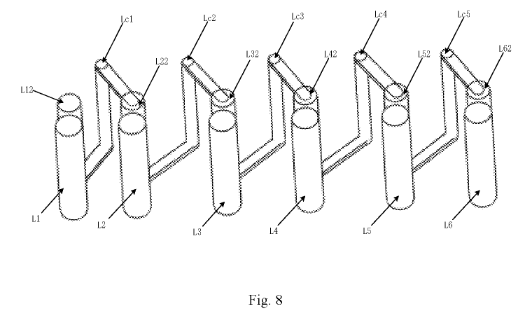

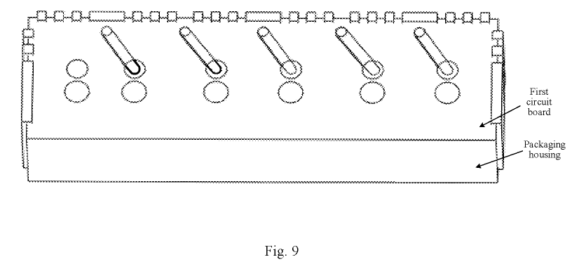

In one embodiment, as shown in FIGS. 8 and FIG. 9, each integrated inductor unit includes six phases of coupling inductor units and five compensation inductors. The secondary winding inductors in the six phases of coupling inductor units and the five compensation inductors are connected in series through the above-mentioned scheme. More details will not be repeated in the present embodiment.

Through the above-mentioned structural design, during the welding operation, it is no longer necessary to add extra routings as in traditional methods to connect both ends of two phases of secondary winding inductors located on different planes, thereby greatly simplifying the welding process and improving the production efficiency. At the same time, external routings have been reduced to reduce potential electrical interferences and fault risks that are possibly caused by complex routings, improve the stability and reliability of the entire inductor module, and also optimize the space layout of the circuit boards, making the module structure more compact.

In one embodiment, referring to FIG. 7, when the secondary winding inductors (L12 and L22) are shorter than the primary circuit inductors (L1 and L2), the internal wire 1 and the internal wire 2 may also be placed directly inside the packaging housing. Under the same connection mode and implementation principle as the first scheme, it is not necessary to integrate the internal wire 1 and the internal wire 2 in the corresponding circuit boards.

When the trans-inductor voltage regulator integrated with the compensation inductors is designed, it is necessary to adjust a distance between the compensation inductor and the adjacent coupling inductor units according to specific circuit performance requirements to obtain a suitable coupling coefficient, thereby optimizing the performances of the circuits. In one embodiment, the coupling coefficient between the compensation inductor and the two adjacent coupling inductor units is less than or equal to a preset value. The present value may be 0.3.

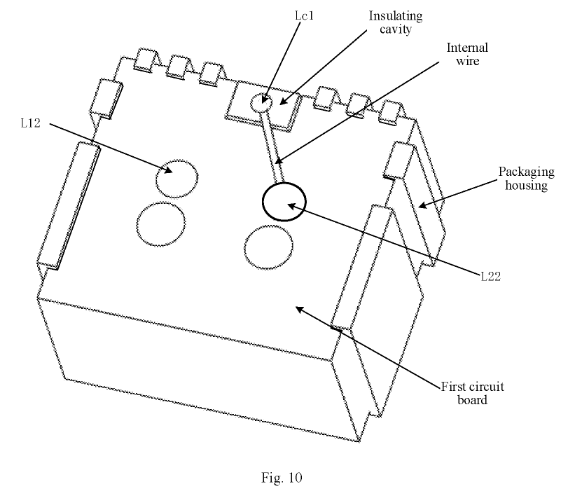

Based on the structure of the first scheme shown in FIGS. 6 and FIG. 7, in the event of not considering the influence of the coupling coefficient between the inductors, in one embodiment, as shown in FIG. 10, the second scheme includes the following content: an insulating cavity may be provided on one side of the packaging housing, the compensation inductor is arranged in the insulating cavity, and both ends of the compensation inductor are exposed from the insulating cavity for connection with the welding spots on the circuit board, respectively. The insulating cavity is provided on one side of the packaging housing, but does not exceed the range of the packaging housing, such that the compensation inductor has an independent magnetic core and winding and is located in the relatively closed insulating cavity, which can avoid the influence caused by the coupling coefficient between the compensation inductor and the adjacent coupling inductor units.

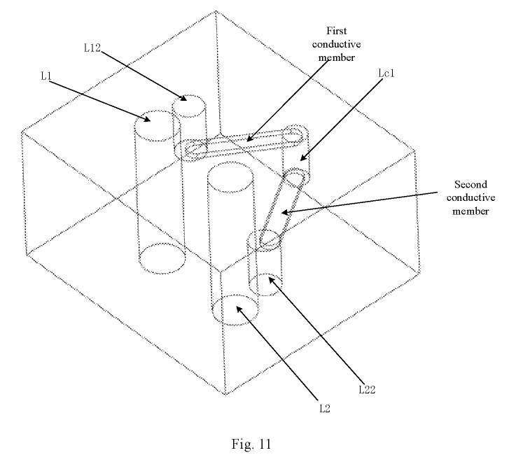

Also, in order to connect both ends of the secondary winding inductors in two adjacent phases of coupling inductor units without additional wires outside the inductor module, the present embodiment further proposes another structure in addition to the scheme in which the internal wires are buried in the first circuit board and the second circuit board. In one embodiment, as shown in FIG. 11, the third scheme includes the following content: a first conductor member and a second conductive member are arranged at least in an inner cavity of the packaging housing; the other end the previous phase of secondary winding inductor is connected to one end of the first conductive member, and the other end of first conductive member is connected to one end of the compensation inductor; and the other end of the compensation inductor is connected to one end of the second conductive member, and the other end of the second conductive member is connected to one end of the next phase of secondary welding inductor.

In FIG. 11, two phases of coupling inductor units are taken as an example. The first and second conductive members are usually made of materials with good conductivity and certain rigidity, such as copper, aluminum and other metal materials. The shapes and sizes of the first and second conductive members may be designed according to an internal space of the packaging housing and the requirements for circuit connection. A complete connection path is constructed inside the packaging housing through the first conductive member and the second conductive member, achieving the connection between both ends of the secondary winding inductors in adjacent coupling inductor units without the need for additional external wires.

In one embodiment, in order to make the third scheme meet practical situations, that is, when each integrated inductor unit includes a plurality of phases of coupling inductor units, it is necessary to ensure that the lengths of the secondary winding inductor in each phase of coupling inductor unit and each compensation inductor are both small enough (i.e., a proportion in a vertical direction is small), such that all devices can be placed in the packaging housing.

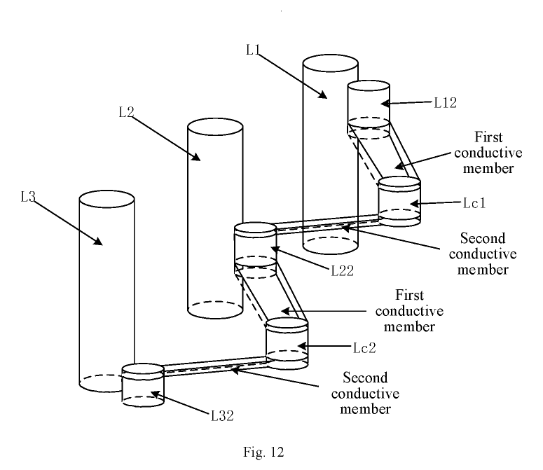

For example, if the secondary winding inductor has the same length as each compensation inductor, a proportion of their length to the length of the primary circuit inductor in a vertical direction is both k. When two phases of coupling inductor units are included, k = 1/3, as shown in FIG. 12; when three phases of coupling inductor units are included, k = 1/5; and when four phases of coupling inductor units are included, k = 1/7, and so on, such that the length of each secondary winding inductor and the length of each compensation inductor can be obtained. According to the above settings for the proportion k of the length of the secondary winding inductor and the length of each compensation inductor in the vertical direction to the length of the primary circuit inductor, it can be ensured that when each integrated inductor unit includes a plurality of phases of coupling inductor units, all devices (including the secondary winding inductors and the compensation inductors) are arranged within the packaging housing, thereby ensuring the structural integrity and completeness of the trans-inductor voltage regulator.

The specific value of k needs to be determined according to actual design requirements, the size limitation of the packaging housing, and the performance requirements of the circuits, etc., and will not be specifically defined in the present embodiment. In one embodiment, in the third scheme, it is also necessary to ensure that the coupling coefficient between the compensation inductor and the two adjacent coupling inductor units is less than or equal to a preset value. The present value may be 0.3.

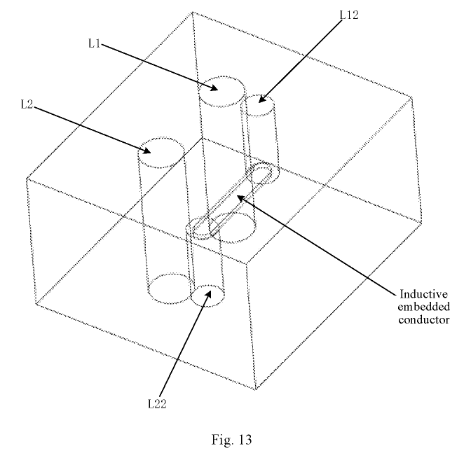

Similarly, in order to connect both ends of the secondary winding inductors in two adjacent phases of coupling inductor units without external additional wires or internal wires buried in the first and second circuit boards, the present embodiment further proposes another structure. In one embodiment, as shown in FIG. 13, the fourth scheme includes the following content: an inductive embedded conductor is provided in the inner cavity of the packaging housing, and the compensation inductor is integrated in the inductive embedded conductor; and the other end the previous phase of secondary winding inductor is connected to one end of the inductive embedded conductor; and the other end of the inductive embedded conductor is connected to one end of the next phase of secondary welding inductor.

The compensation inductor is integrated into the inductive embedded conductor, and both ends of the two adjacent secondary winding inductors are directly connected through the inductive embedded conductor. In order to save the internal space of the packaging housing, in one embodiment, the inductive embedded conductor may be arranged in parallel to the second circuit board. FIG. 13 shows two phases of coupling inductor units and an inductive embedded conductor. Similarly, when a plurality of phases of coupling inductor units are included, it is necessary to ensure that the length of the secondary winding inductor in each phase of coupling inductor unit is small enough in the vertical direction (that is, a proportion occupied in the vertical direction is small). In the horizontal direction, it is necessary to ensure that the length of the inductive embedded conductor is also small enough (that is, a proportion of a distance between the primary circuit inductor in the first phase of coupling inductor unit and the last phase of coupling inductor unit in the horizontal direction is small).

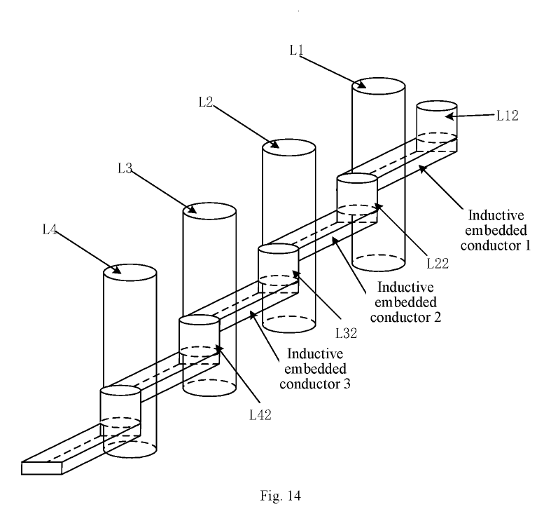

For example, if a proportion of the length of each secondary winding inductor to the length of the primary circuit inductor in the vertical direction is x, a proportion of the length of the inductive embedded conductor in the horizontal direction to the total length from the first phase of primary circuit inductor to the last phase of primary circuit inductor is y. When two phases of coupling inductor units are included, x = 1/2, y = 1; when three phases of coupling inductor units are included, x = 1/3, y = 1/2; and as shown in FIG. 14, when four phases of coupling inductor units are included, x = 1/4, y = 1/3, and so on, such that the length of each secondary winding inductor and the length of each inductive embedded conductor can be obtained. According to the above settings for the proportion x of the length of the secondary winding inductor and the length of each compensation inductor in the vertical direction to the length of the primary circuit inductor and the proportion y of the length of the secondary winding inductor and the length of each compensation inductor in the horizontal direction to the total length from the first phase of primary circuit inductor to the last phase of primary circuit inductor, it can be ensured that when each integrated inductor unit includes a plurality of phases of coupling inductor units, all devices (including the secondary winding inductors and the compensation inductors) are arranged within the packaging housing, thereby ensuring the structural integrity and completeness of the trans-inductor voltage regulator.

The specific values of x and y need to be determined according to actual design requirements, the size limitation of the packaging housing, and the performance requirements of the circuits, etc., and will not be specifically defined in the present embodiment.

Four different schemes are proposed in the above embodiment to connect both ends of the secondary winding inductors in two adjacent phases of coupling inductor units in sequence without using external additional wires. Without considering the influences of the lengths of the secondary winding inductors and the compensation inductors, in the first scheme, the second scheme and the third scheme, a preset angle may be formed between the compensation inductor and the second circuit board. In order to save the space, the preset angle may be 90°. In the fourth scheme, in order to save the space, the inductive embedded conductor may be arranged in parallel to the second circuit board.

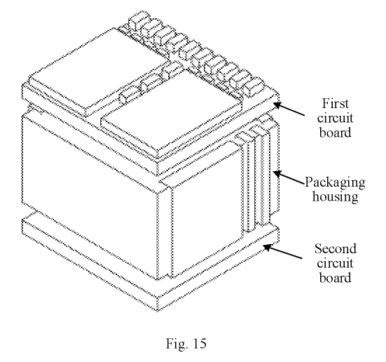

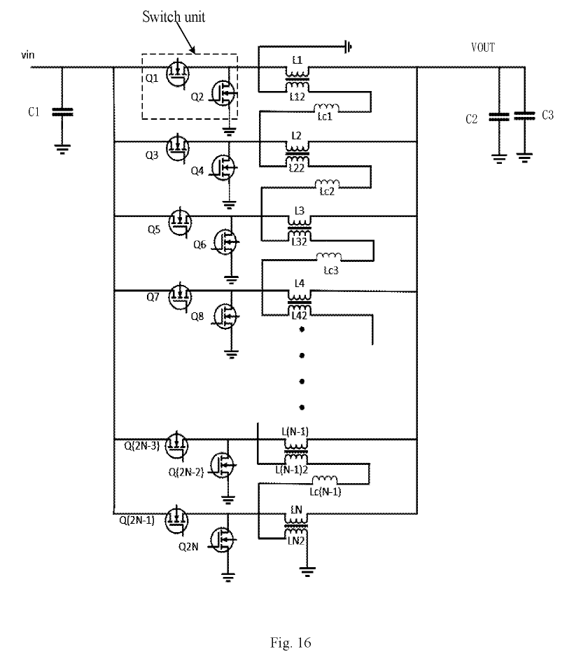

In one embodiment, as shown in FIGS. 15 and FIG. 16, the trans-inductor voltage regulator integrated with the compensation inductors further includes a plurality of switch units, wherein each coupling inductor unit is correspondingly connected to one switch unit; the switch unit includes a first switch tube (i.e., Q1, Q3, Q5 or Q7) and a second switch tube (i.e., Q2, Q4, Q6 or Q8) which are both arranged on the first circuit board; and one end of the first switch tube is used for connection with an input voltage, the other end of the first switch tube is respectively connected to one end of the second switch tube and one end of the primary circuit inductor, and the other end of the second switch tube is grounded.

Each phase of coupling inductor unit corresponds to one switch unit, that is, each phase of coupling inductor unit includes a first switch tube and a second switch tube. The first switch tube and the second switch tube are periodically turned on and off, and an input voltage (Vin) is chopped into a pulse signal by means of a high-frequency switching action to control the energy storage and release of the trans-inductor voltage regulator.

In the turn-on stage, when the first switch tube (e.g., Q1) is turned on, the input voltage charges the primary circuit inductor, the current rises linearly, and the energy is stored in the primary circuit inductor. After the first switch tube is turned off, the second switch tube (e.g., Q2) is turned on (synchronously rectified), the current in the primary circuit inductor undergoes low-side freewheeling, and the energy is released to the load. A turn-on time ratio (i.e., a duty cycle of the switch tube) is adjusted in real time according to the load change to maintain the stability of an output voltage (Vout). In one embodiment, a PWM controller corresponding to the switch tube monitors the feedback of the output voltage Vout, increases the duty cycle to quickly replenish energy when the load suddenly increases, and decreases the duty cycle to prevent overshoot when the load decreases.

In one embodiment, referring to FIG. 16, the trans-inductor voltage regulator integrated with the compensation inductors further includes an input filter unit and an output filter unit, wherein one end of the input filter unit is connected to the input voltage, and the other end of the input filter unit is grounded; and one end of the output filter unit is connected to one end of the primary circuit inductor, and the other end of the output filter unit is grounded. The input filter unit and the output filter unit are both arranged on the first circuit board or the second circuit board.

The input filter unit includes a capacitor C1, and the output filter unit includes capacitors C2 and C3. The input voltage often contains various high-frequency noises and interference signals, which may have adverse effects on the normal operation of the circuits inside the module. The main function of the input filter unit is to filter out these high-frequency noises and interference signals.

The input filter unit and the output filter unit work together to provide a good filtering effect for the entire trans-inductor voltage regulator integrated with the compensation inductors. The input filter unit ensures the purity of the input voltage and reduces the impact of external interferences on the circuits inside the module. The output filter unit guarantees the stability and high quality of the output voltage, and meets the requirements of load equipment for the power supply.

In the present embodiment, the coupling inductor units and the compensation inductors are all integrated in the packaging housing, and the compensation inductor is connected in series between every two adjacent phases of secondary winding inductors; both ends of the compensation inductor may be arranged on different planes, respectively; and in the connection of two adjacent phases of secondary winding inductors, a tail end of the previous phase of secondary winding inductor and one end of the corresponding compensation inductor are located on the same welding face, and a head end of the next phase of secondary winding inductor and the other end of the corresponding compensation inductor are located on the same welding face. That is, it is ensured that both ends of the compensation inductor are located on the same welding face as both ends of the corresponding secondary winding inductor, the problem of line connection is solved, and no external routing is needed, such that the structure of the trans-inductor voltage regulator is more concise.

### Embodiment 2

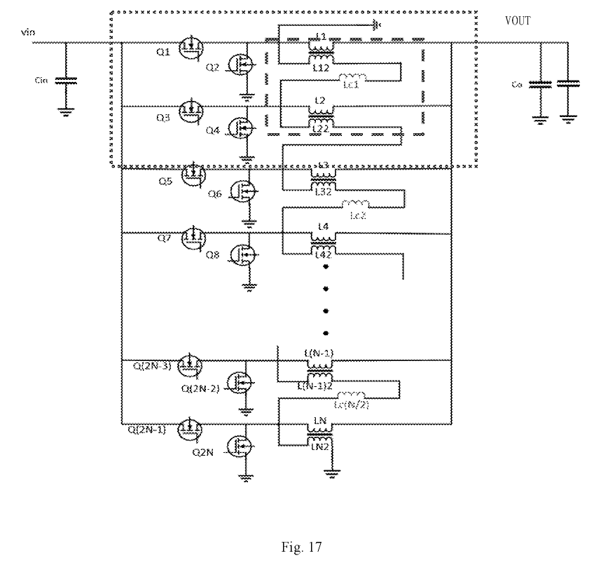

In some application scenarios, on the premise of not considering the issue that both ends of secondary winding inductors in a plurality of phases of coupling inductor units are not on the same welding face and external wires are required to connect both ends of two adjacent phases of secondary winding inductors, as shown in FIG. 17, a compensation inductor may also be connected in series between the secondary winding inductors in every two phases of coupling inductor units, that is, N/2 compensation inductors need to be provided when N phases of coupling inductor units are included.

In other embodiments, in the design of the trans-inductor voltage regulator integrated with N (N>2) phases of coupling inductor units, the compensation inductor may be placed between any two adjacent phases as required. In Embodiment 1, since it is considered that both ends of the secondary winding inductors in the adjacent phases of coupling inductor units are connected through the compensation inductor, no external routing is required for connection, that is, the compensation inductor is placed between every two adjacent phases. In one embodiment, any number of compensation inductors at any position may be selected among the N secondary winding inductors according to actual needs. A high voltage borne by the original independent compensation inductor is evenly distributed on a plurality of compensation inductors, and the value of voltage borne by each compensation inductor is greatly reduced, thereby ensuring the stability of the trans-inductor voltage regulator.

### Embodiment 3

In order to further describe the trans-inductor voltage regulators integrated with the compensation inductors proposed in Embodiment 1 and Embodiment 2, the present embodiment proposes a power module. The power module includes at least one trans-inductor voltage regulator integrated with compensation inductors.

In the present embodiment, the coupling inductor units and the compensation inductors are all integrated in the packaging housing, and the compensation inductor is connected in series between every two adjacent phases of secondary winding inductors; both ends of each compensation inductor may be arranged on different planes, respectively; and in the connection of two adjacent phases of secondary winding inductors, a tail end of the previous phase of secondary winding inductor and one end of the corresponding compensation inductor are located on the same welding face, and a head end of the next phase of secondary winding inductor and the other end of the corresponding compensation inductor are located on the same welding face. That is, it is ensured that both ends of the compensation inductor are located on the same welding face as both ends of the corresponding secondary winding inductor, the problem of line connection is solved, and no external routing is needed, such that the structure of the trans-inductor voltage regulator is more concise.

In another aspect, in the present embodiment, a high voltage borne by the original independent compensation inductor is evenly distributed on a plurality of compensation inductors, and the value of voltage borne by each compensation inductor is greatly reduced, thereby ensuring the stability of the trans-inductor voltage regulator.

The specific structure of the trans-inductor voltage regulator integrated with the compensation inductors is shown in Embodiment 1, and will not be repeated in the present embodiment.

The foregoing descriptions are merely preferred embodiments of the present invention, and are not intended to limit the present invention. Within the spirit and principles of the present invention, any modifications, equivalent substitutions, improvements, etc., are within the protection scope of the present invention.

What is claimed is:

1. A trans-inductor voltage regulator integrated with compensation inductors, comprising a packaging housing, a first circuit board, a second circuit board and integrated inductor units arranged between the first circuit board and the second circuit board, wherein the first circuit board and the second circuit board are arranged on both sides of the packaging housing, respectively;
each integrated inductor unit comprises a plurality of coupling inductor units and at least one compensation inductor; at least one compensation inductor is arranged between every two adjacent coupling inductor units; each coupling inductor unit comprises a primary circuit inductor and a secondary winding inductor, and the secondary winding inductor is coupled with the primary circuit inductor;
one end of the primary circuit inductor is used for connection with an input voltage, and the other end of the primary circuit inductor is used for connection with a power consumption end; and
one end of the compensation inductor is connected to the previous phase of secondary winding inductor, and the other end of the compensation inductor is connected to the next phase of secondary winding inductor.

2. The trans-inductor voltage regulator integrated with compensation inductors according to claim 1, wherein the first circuit board is provided with at least a first welding spot, a second welding spot and a third welding spot; the second circuit board is provided with at least a fourth welding spot, a fifth welding spot and a sixth welding spot;
the second welding spot and the third welding spot are connected through an internal wire in the first circuit board; the fourth welding spot and the fifth welding spot are connected through an internal wire in the second circuit board; and
one end of the previous phase of secondary winding inductor is connected to the first welding spot, and the other end of the previous phase of secondary welding inductor is connected to the fourth welding spot; one end of the compensation inductor is connected to the fifth welding spot, and the other end of the compensation inductor is connected to the second welding spot; and one end of the next phase of secondary welding inductor is connected to the third welding spot, and the other end of the next phase of secondary welding inductor is connected to the sixth welding spot.

3. The trans-inductor voltage regulator integrated with compensation inductors according to claim 2, wherein an insulating cavity is provided on one side of the package housing, each compensation inductor is arranged in the insulating cavity, and both ends of the compensation inductor are exposed from the insulating cavity.

4. The trans-inductor voltage regulator integrated with compensation inductors according to claim 2, further comprising a plurality of switch units, wherein each coupling inductor unit corresponds to one switch unit, and the switch unit comprises a first switch tube and a second switch tube which are both arranged on the first circuit board; and
one end of the first switch tube is used for connection with the input voltage, the other end of the first switch tube is respectively connected to one end of the second switch tube and one end of the primary circuit inductor, and the other end of the second switch tube is grounded.

5. The trans-inductor voltage regulator integrated with compensation inductors according to claim 2, further comprising an input filter unit and an output filter unit, wherein one end of the input filter unit is connected to the input voltage, and the other end of the input filter unit is grounded; and one end of the output filter unit is connected to one end of the primary circuit inductor, and the other end of the output filter unit is grounded.

6. The trans-inductor voltage regulator integrated with compensation inductors according to claim 2, wherein a coupling coefficient between each compensation inductor and two adjacent coupling inductor units is less than or equal to a preset value.

7. The trans-inductor voltage regulator integrated with compensation inductors according to claim 2, wherein a preset angle is formed between the compensation inductor and the second circuit board.

8. The trans-inductor voltage regulator integrated with compensation inductors according to claim 1, wherein a first conductive member and a second conductive member are arranged at least in an inner cavity of the packaging housing; and
the other end the previous phase of secondary winding inductor is connected to one end of the first conductive member, and the other end of first conductive member is connected to one end of the compensation inductor; the other end of the compensation inductor is connected to one end of the second conductive member, and the other end of the second conductive member is connected to one end of the next phase of secondary welding inductor.

9. The trans-inductor voltage regulator integrated with compensation inductors according to claim 8, further comprising a plurality of switch units, wherein each coupling inductor unit corresponds to one switch unit, and the switch unit comprises a first switch tube and a second switch tube which are both arranged on the first circuit board; and
one end of the first switch tube is used for connection with the input voltage, the other end of the first switch tube is respectively connected to one end of the second switch tube and one end of the primary circuit inductor, and the other end of the second switch tube is grounded.

10. The trans-inductor voltage regulator integrated with compensation inductors according to claim 8, further comprising an input filter unit and an output filter unit, wherein one end of the input filter unit is connected to the input voltage, and the other end of the input filter unit is grounded; and one end of the output filter unit is connected to one end of the primary circuit inductor, and the other end of the output filter unit is grounded.

11. The trans-inductor voltage regulator integrated with compensation inductors according to claim 8, wherein a coupling coefficient between each compensation inductor and two adjacent coupling inductor units is less than or equal to a preset value.

12. The trans-inductor voltage regulator integrated with compensation inductors according to claim 1, wherein an inductive embedded conductor is provided in the inner cavity of the packaging housing, and the compensation inductor is integrated in the inductive embedded conductor; and
the other end of the previous phase of secondary winding inductor is connected to one end of the inductive embedded conductor; and the other end of the inductive embedded conductor is connected to one end of the next phase of secondary welding inductor.

13. The trans-inductor voltage regulator integrated with compensation inductors according to claim 12, further comprising a plurality of switch units, wherein each coupling inductor unit corresponds to one switch unit, and the switch unit comprises a first switch tube and a second switch tube which are both arranged on the first circuit board; and
one end of the first switch tube is used for connection with the input voltage, the other end of the first switch tube is respectively connected to one end of the second switch tube and one end of the primary circuit inductor, and the other end of the second switch tube is grounded.

14. The trans-inductor voltage regulator integrated with compensation inductors according to claim 12, further comprising an input filter unit and an output filter unit, wherein one end of the input filter unit is connected to the input voltage, and the other end of the input filter unit is grounded; and one end of the output filter unit is connected to one end of the primary circuit inductor, and the other end of the output filter unit is grounded.

15. The trans-inductor voltage regulator integrated with compensation inductors according to claim 12, wherein a coupling coefficient between each compensation inductor and two adjacent coupling inductor units is less than or equal to a preset value.

16. The trans-inductor voltage regulator integrated with compensation inductors according to claim 1, further comprising a plurality of switch units, wherein each coupling inductor unit corresponds to one switch unit, and the switch unit comprises a first switch tube and a second switch tube which are both arranged on the first circuit board; and
one end of the first switch tube is used for connection with the input voltage, the other end of the first switch tube is respectively connected to one end of the second switch tube and one end of the primary circuit inductor, and the other end of the second switch tube is grounded.

17. The trans-inductor voltage regulator integrated with compensation inductors according to claim 1, further comprising an input filter unit and an output filter unit, wherein one end of the input filter unit is connected to the input voltage, and the other end of the input filter unit is grounded; and one end of the output filter unit is connected to one end of the primary circuit inductor, and the other end of the output filter unit is grounded.

18. The trans-inductor voltage regulator integrated with compensation inductors according to claim 1, wherein a coupling coefficient between each compensation inductor and two adjacent coupling inductor units is less than or equal to a preset value.

19. The trans-inductor voltage regulator integrated with compensation inductors according to claim 1, wherein a preset angle is formed between the compensation inductor and the second circuit board.

20. A power module, comprising at least one trans-inductor voltage regulator integrated with compensation inductors according to claim 1.
